(19) United States
(12) Patent Application Publication
(10) Pub. No.: US 2017/0018812 A1
(43) Pub. Date: Jan. 19, 2017

(54) Method of Manufacturing a Battery, Battery and Integrated Circuit

(71) Applicant: Infineon Technologies AG, Neubiberg (DE)

(72) Inventors: Kamil Karlovsky, Villach (AT); Andreas Dunst, Kapfenberg (AT); Georg Hirtler, Graz (AT); Rafael Janski, Villach (AT); Katharina Schmut, Drollbach (AT); Michael Sorger, Villach (AT); Michael Sternad, Graz (AT); Martin Wilkening, Graz (AT)

(21) Appl. No.: 15/210,283

(22) Filed: Jul. 14, 2016

(30) Foreign Application Priority Data
Jul. 15, 2015 (DE) 102015111497.6

(51) Int. Cl. H01M 10/42; H01M 10/058; H01L 27/06; H01M 4/38; H01M 4/134; H01M 4/66; H01M 10/0525; H01M 2/16

(52) U.S. Cl. CPC H01M 10/425; H01M 10/0525; H01M 10/058; H01M 2/1613; H01M 2/162; H01M 2/1626; H01M 2/1673; H01M 2/1666; H01M 4/386; H01M 4/134; H01M 4/66; H01L 27/0688; H01M 2220/30

(57) ABSTRACT

A method of manufacturing a battery includes introducing a suspension comprising a solvent and fibers into a cavity for housing an electrolyte, drying the solvent, filling the electrolyte into the cavity, and closing the cavity.

### PRIORITY CLAIM

This application claims priority to German Patent Application No. 10 2015 111 497.6 filed on 15 Jul. 2015, the content of said application incorporated herein by reference in its entirety.

### BACKGROUND

With the increased use of portable electronic devices such as notebooks, portable telephones, cameras and others and with the increased use of current-driven automobiles, lithium ion secondary batteries with high energy density have attracted increasing attention as a power source.

Further, attempts are being made for providing semiconductor devices or semiconductor-based devices having an integrated power source.

Lithium ion secondary batteries typically include a cathode comprising a lithium-containing transition metal oxide or the like, an anode typically made of a carbon material and a non-aqueous electrolyte containing a lithium salt as well as a separator situated between the anode and the cathode.

In order to meet the increasing demands on capacity and performance, new concepts for lithium batteries that can be manufactured in a simple manner are desirable.

In particular, further concepts of separators that may be used in lithium batteries are investigated.

### SUMMARY

According to an embodiment, a method of manufacturing a battery comprises introducing a suspension comprising a solvent and fibers into a cavity for housing an electrolyte, drying the solvent, filling the electrolyte into the cavity, and closing the cavity.

According to a further embodiment, a method of manufacturing a battery comprises patterning a first main surface of a first semiconductor substrate to form a patterned portion in the first main surface, forming an anode at the patterned portion, forming a cathode at a carrier comprising an insulating material, filling a suspension comprising a solvent and fibers into the patterned portion, drying the solvent to form a separator, filling an electrolyte into the patterned portion, and stacking the first semiconductor substrate and the carrier so that the first main surface of the first semiconductor substrate is disposed on a side adjacent to a first main surface of the carrier.

According to an embodiment, a battery comprises a first semiconductor substrate having a first main surface, an anode at the first semiconductor substrate, a carrier comprising an insulating material, the carrier having a first main surface, and a cathode at the carrier, the first semiconductor substrate and the carrier being stacked so that the first main surface of the first semiconductor substrate is disposed on a side adjacent to the first main surface of the carrier, a cavity being formed between the first semiconductor substrate and the carrier. The battery further comprises a separator comprising fibers and a binder in the cavity and an electrolyte in the cavity.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIGS. 1A to 1D illustrate a method of manufacturing a battery according to an embodiment.

FIG. 2 shows a flowchart of a method of manufacturing a battery according to an embodiment.

FIGS. 3A to 3H illustrate a method of manufacturing a battery according to a further embodiment.

FIG. 4 shows a flowchart of a method of manufacturing a battery according to a further embodiment.

FIG. 5 illustrates a battery according to an embodiment.

Those skilled in the art will recognize additional features and advantages upon reading the following detailed description, and upon viewing the accompanying drawings.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “leading”, “trailing” etc. is used with reference to the orientation of the figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer”, “substrate” or “semiconductor substrate” used in the following description may include any semiconductor-based structure that has a semiconductor surface. Wafer and structure are to be understood to include silicon, silicon-on-insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could as well be silicon-germanium, germanium, or gallium arsenide. According to other embodiments, silicon carbide (SiC) or gallium nitride (GaN) may form the semiconductor substrate material.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

The terms “lateral” and “horizontal” as used in this specification intends to describe an orientation parallel to a first surface of a semiconductor substrate or semiconductor body. This can be for instance the surface of a wafer or a die.

The term “vertical” as used in this specification intends to describe an orientation which is arranged perpendicular to the first surface of the semiconductor substrate or semiconductor body.

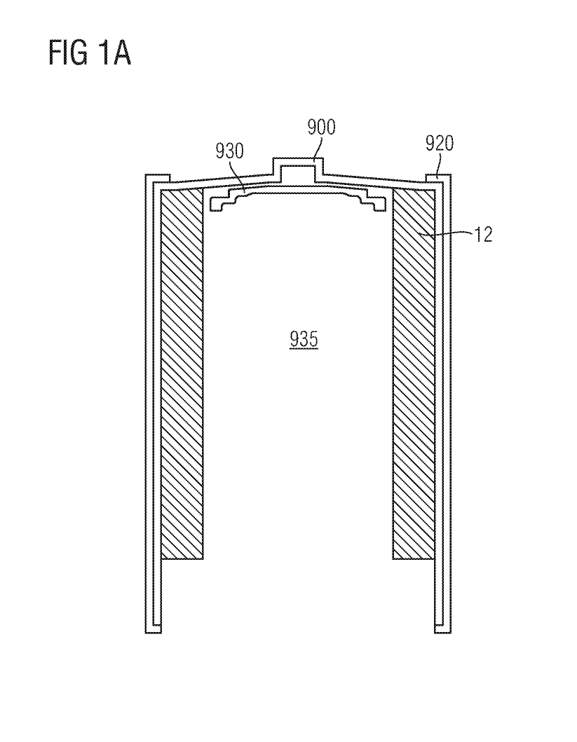

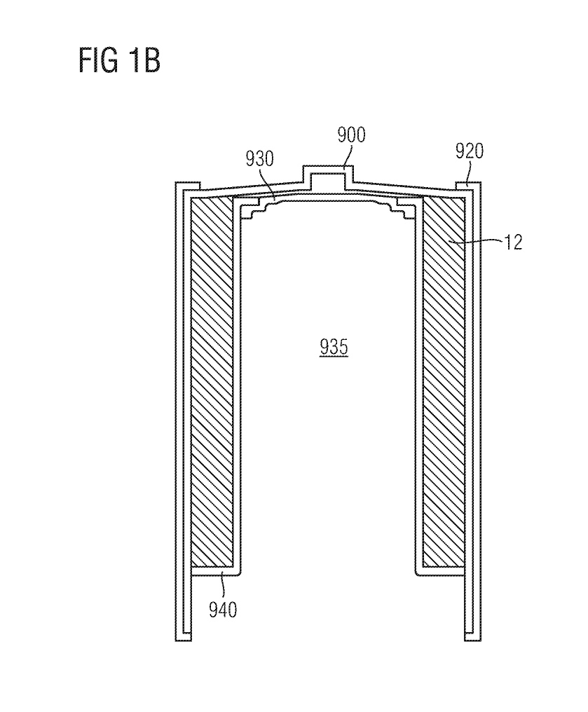

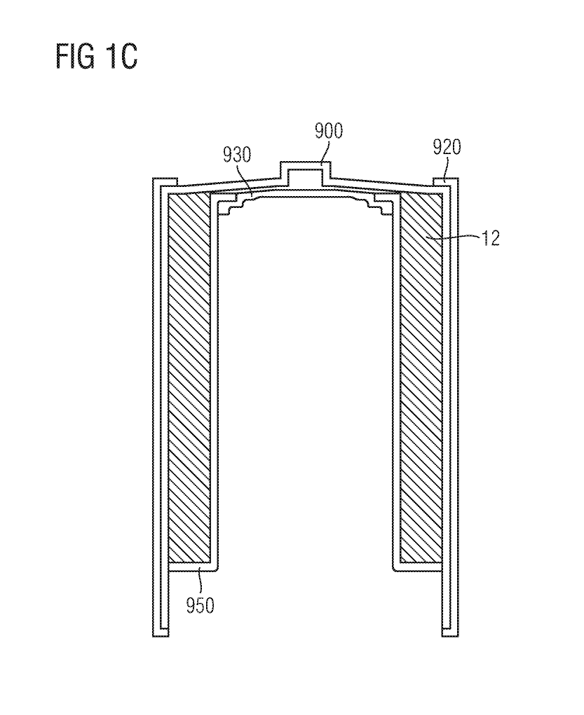

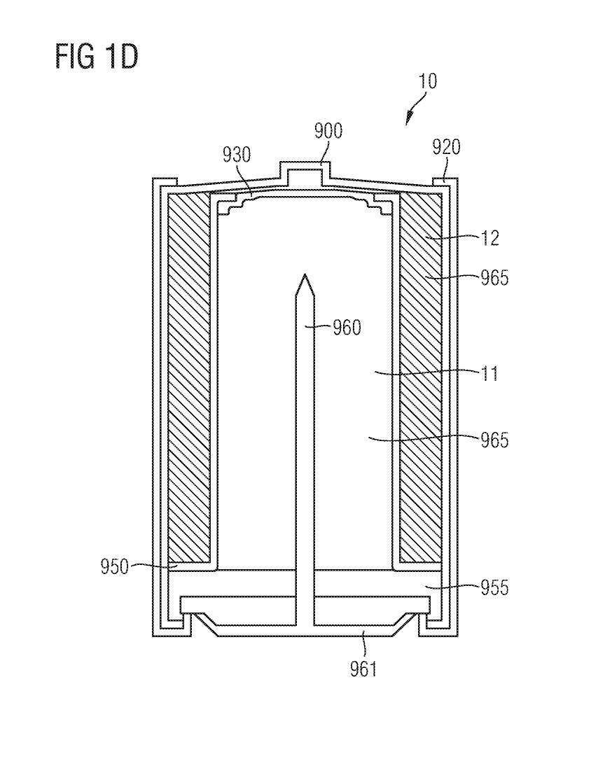

FIGS. 1A to 1D illustrate a method of manufacturing a battery according to an embodiment. A cavity 935 for housing an electrolyte 965 is formed or provided. For example, this may be accomplished by assembling elements of a housing 900 or by appropriately shaping a housing material. For example, as is shown in FIG. 1A, a cup of a conductive material such as a metal may be appropriately shaped so that an electrode of the battery may be formed. A cathode 12 is formed adjacent to an inner sidewall of the housing 900. Further an insulating material 930 may be formed on an uncovered inner top side of the housing 900. A further insulating material 920 may be formed on an outer sidewall of the housing 900. FIG. 1A shows an example of a resulting structure.

Thereafter, a suspension 940 which comprises a solvent and fibers is introduced into the cavity 935. For example, the suspension may be formed on sidewalls of the cathode 12. The term “introducing a suspension” means that a thin layer of the suspension may be applied over a sidewall of the housing 900 or in the housing 900. According to embodiments, the suspension 940 may be introduced by arbitrary methods such as pipetting, spinning, spraying and others. FIG. 1B shows an example of a resulting structure.

As is shown, the suspension 940 is formed so as to cover the cathode 12. Thereafter, the solvent is dried. This may be accomplished by heating the battery. As a result, a thin film of the separator 950 is formed so as to cover the cathode 12. FIG. 1C shows an example of a resulting structure.

Thereafter, the electrolyte is filled into the cavity and the cavity 935 is closed. In the example shown in FIG. 1D, an anode 11 is arranged in the cavity and a conducting element 960 for electrically connecting the anode 11 to an external terminal is formed inside the cavity 935. The bottom side of the conducting material 960 forms a lid 961 of the battery. The conducting element 960 is insulated from further elements of the battery 10 by means of the insulating material 955.

According to another embodiment, the anode 11 may be integrated with the lid.

The separator 950 spatially and electrically separates the anode 11 and the cathode 12 from each other.

The separator 950 should be permeable for the ions so that a conversion of the stored chemical energy into electrical energy may be accomplished. The main function of a separator is to keep the two electrodes apart to prevent electrical short-circuits while also allowing the transport of ionic charge carriers. The separator should be an electrical isolator and should be stable during the electro-chemical reactions that take place in the battery.

Forming the separator comprises introducing a suspension comprising a solvent and fibers into the cavity. Examples of the solvent comprise water and PVDF (polyvinylidene fluoride). Examples of the fibers comprise borosilicate 33 glass fibers, polyethylene/polypropylene fibers, ZrO₂ fibers, Al₂O₃ fibers, SiO₂ fibers, polyimide fibers, paper fibers and cellulose fibers. Further, a binder may be used such as PVDF, Na-Carboxy methyl cellulose, styrol butadiene rubber and others. Further binders that may be used should be stable in the electrochemical window which is defined by the electrode materials. A composition ratio of the fibers and the binder may be 0.5 to 10% binder, 99.5 to 90% fibers. The composition ratio of the solvent depends on the needed viscosity. For example, a ratio of the liquid to the solid components may be 1:1. Fibers from a whatman glass fiber filter may be used with water at a composition ratio of 1%. A thickness of the resulting separator is 10 to 10 000 μm. According to an example, the fibers may be a spin material, that are commercially available as fibers or filters.

The battery comprises a primary cell or a secondary cell. Examples of primary batteries comprise alkaline batteries, zinc-carbon batteries, lithium-based batteries and others. Examples of secondary or rechargeable batteries comprise lead-acid, nickel-cadmium, nickel-metal hydride (NiMh), lithium-ion (Li-ion), lithium-ion-polymer (Li-ion polymer), aluminium-ion (Al-ion) and further batteries.

Due to the special method of forming the separator from a suspension directly in the cavity of the battery, the separator may be produced at reduced cost and no manual picking and placing process is necessary. In particular, applying or introducing the suspension may be performed in an automated manner using an adequate equipment such as a pipette or an appropriate spraying or application tool. The intrinsic properties of the separator such as the porosity, the thickness, the lateral dimensions, the elastic modules may be adjusted and the chemical surface characteristics may be modified. For example, this may be accomplished by adjusting the composition ratio of fibers to binder and by selecting an appropriate binder.

As is shown in FIG. 1D, a battery may comprise an anode, a cathode, and a separator between the anode and the cathode. The separator comprises fibers and a binder. The anode, the cathode and the separator may be disposed in a cavity. Further, a electrolyte is disposed in the cavity.

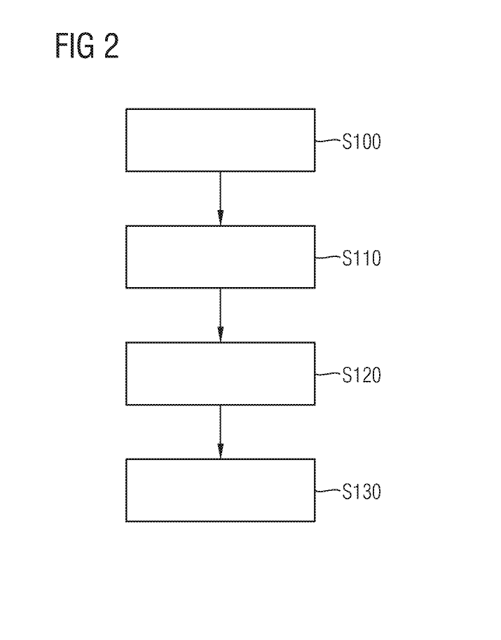

FIG. 2 summarizes a method of manufacturing a battery. As is illustrated in FIG. 2, the method comprises introducing a suspension containing a solvent and fibers into a cavity (S100) for housing an electrolyte (S100), drying the solvent (S110), filling the electrolyte into the cavity (S120), and closing the cavity (S130). As has been explained above, “introducing” may comprise applying, spinning, spraying or forming a layer of the suspension.

A method of manufacturing a battery according to a further embodiment will be explained in the following. The method employs a semiconductor substrate. Accordingly, general semiconductor processing methods may be employed. For example, the semiconductor processing methods may be performed on a wafer level so as to manufacture a plurality of batteries in parallel. After manufacturing the batteries, the single batteries may be isolated or separated by performing a wafer dicing or sawing process. For example, methods for manufacturing miniaturized sizes can effectively applied for manufacturing a battery having a small size in comparison to conventional batteries. Further, components of integrated circuits may be easily integrated with the battery. The following description describes a general embodiment of a method of manufacturing a battery. Specific examples of materials employed will be discussed later with reference to FIG. 5.

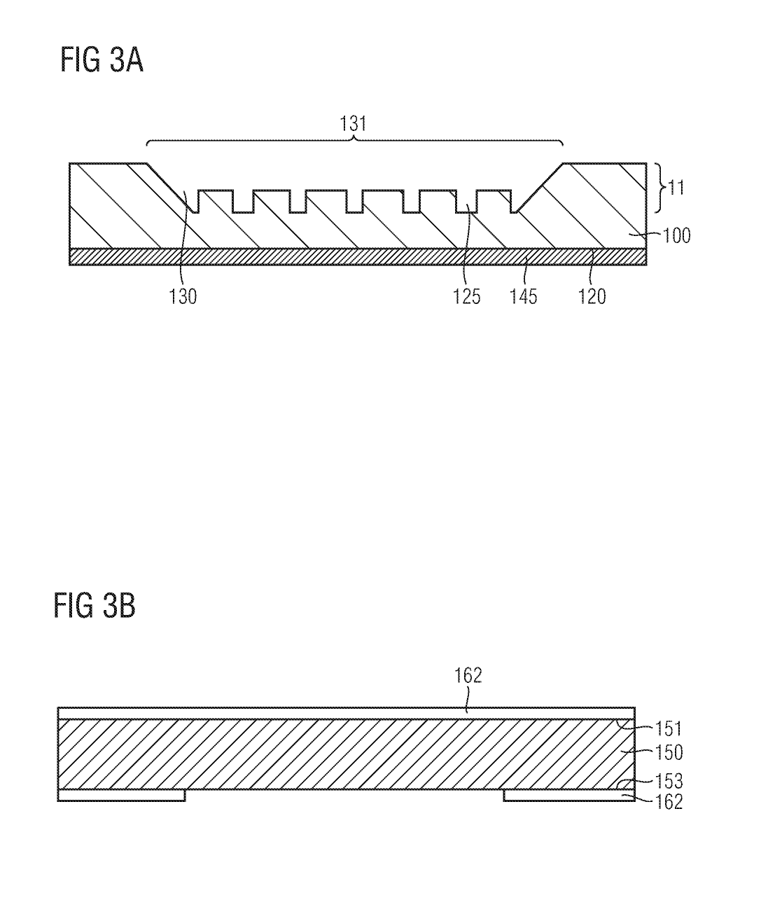

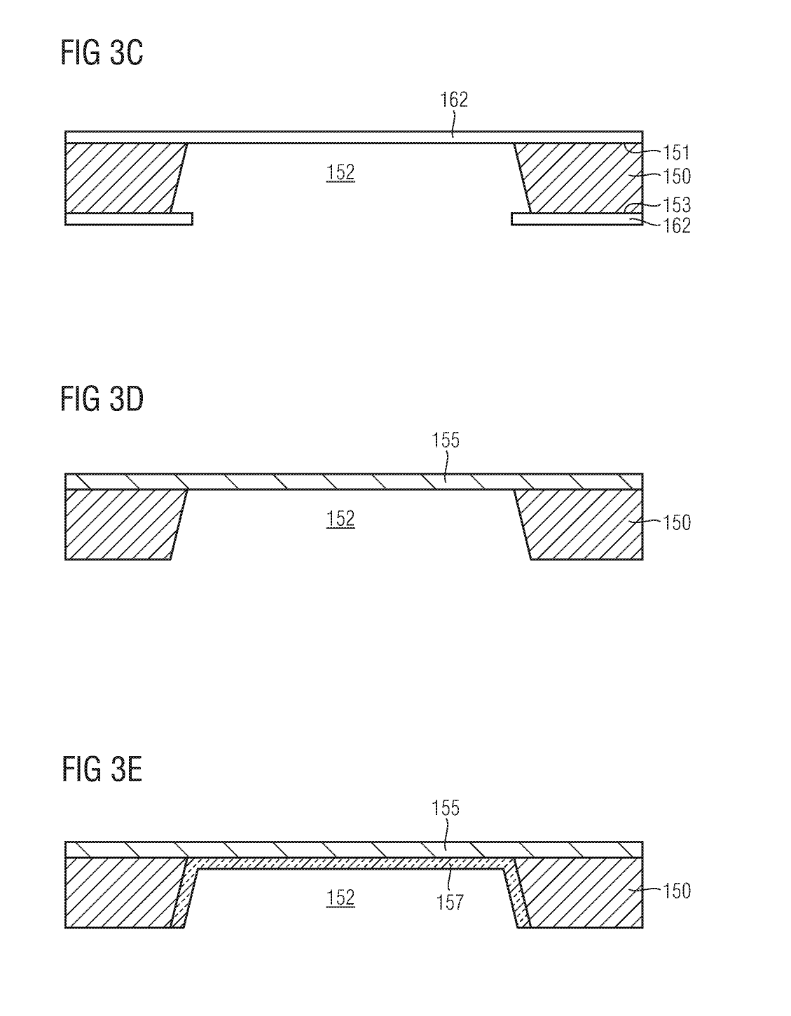

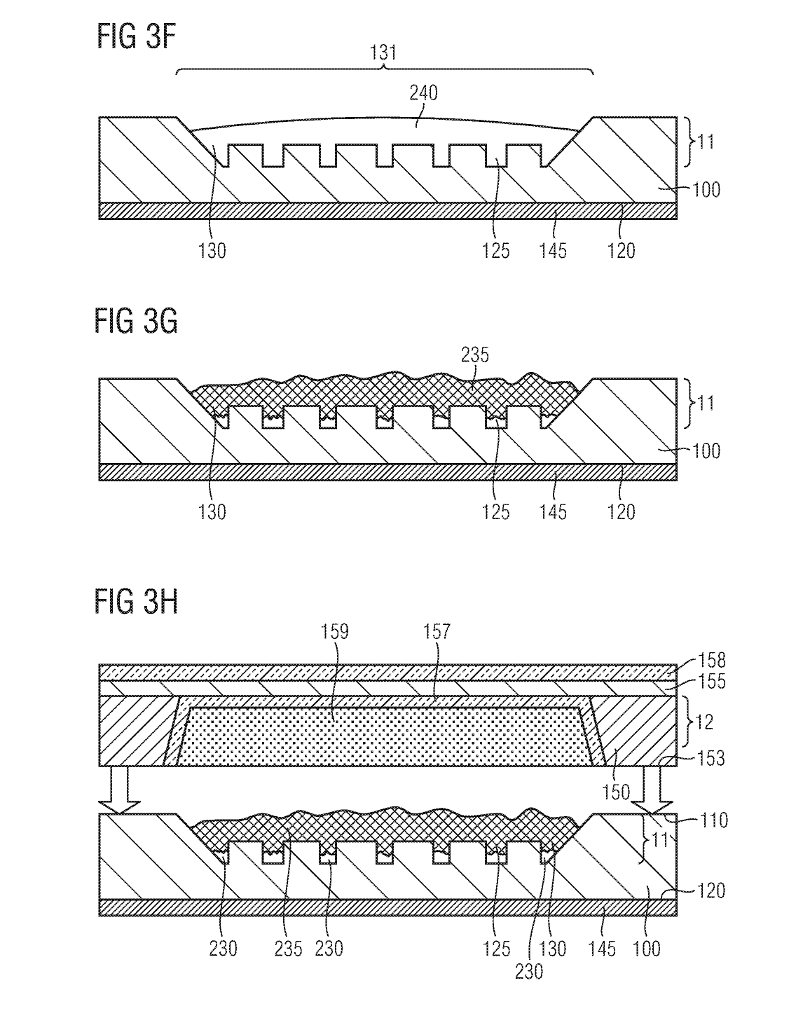

A first semiconductor substrate 100 which may comprise silicon is processed to form an anode 11 of a lithium ion battery. For example, a patterned portion 131 is formed in the first semiconductor substrate 100. The patterned portion 131 may comprise a depression 130. The patterned portion may further comprise trenches 125. For example, the depression 130 may have a depth of 0 to 300 μm, e.g. 0 to 200 μm. The trenches may have a width of approximately 10 to 100 μm, e.g. 25 to 50 μm. The distance between adjacent trenches may be 25 to 100 μm. e.g. 40 to 60 μm. A back side metallization (element) 145 may be formed on the second main surface 120 of the first semiconductor substrate 100. FIG. 3A illustrates a cross-sectional view of an example of a resulting first semiconductor substrate 100.

Then, a carrier 150 comprising an insulating material is processed to form a cathode. For example, the carrier 150 may be a glass wafer or any other wafer made of an insulating material. For example, a hard mask layer 162 is formed adjacent to a first main surface 153 and a second main surface 151 of the carrier 150. The hard mask layer 162 is patterned to form an opening for etching an opening in the glass carrier (FIG. 3B).

Thereafter, an etching step, e.g. using HF (hydrofluoric acid) as an etchant is performed so as to form an opening 152 in the carrier 150. The opening 152 is formed so as to extend from the first main surface 153 to the second main surface 151 (FIG. 3C).

After removing the residues of the hard mask layer 162, a planar second substrate 155 comprising a semiconductor or conductive material may be bonded with the carrier, e.g. using anodic bonding or another bonding method suitable for bonding planar surfaces. (FIG. 3D)

Thereafter, a protective conductive layer 157 such as an aluminium layer may be formed on the surface of the resulting opening 152. Any material that may prevent a contact of the lithium source and the material of the second substrate 155 may be used as the material of the protective conductive layer 157. Due to the presence of the protective conductive layer 157, diffusion of the lithium atoms in the material of the second substrate 155 may be prevented. This is useful in case the second substrate 155 comprises a semiconductor material. FIG. 3E shows a cross-sectional view of a resulting structure.

A conductive layer 158 is formed on the top surface of the second substrate 155 so as to provide an electrical contact. Further, a lithium source 159 is filled into the opening 152. When assembling the first substrate 100 and the carrier 150, a cavity 154 is formed. According to the embodiment, the cavity 154 is formed between the first semiconductor substrate 100, the carrier 150 and the semiconductor wafer 155. For example, the cavity may comprise the recessed portion 130, the trenches 125 and/or the opening 152.

A suspension which comprises a solvent and fibers is filled into the patterned portion 131 formed in the first semiconductor substrate 100. For example, the suspension may be filled so as to fill the spaces between adjacent trenches 125 in the first semiconductor substrate 100. FIG. 3F shows an example of a resulting structure. The suspension may have the composition as has been explained above with reference to FIGS. 1A to 1D.

Thereafter, the solvent of the suspension is dried. For example, this may be accomplished by heating the suspension to a temperature of approximately 100° C. Thereafter, an electrolyte is filled into the patterned portion 131 which contains the dried separator. FIG. 3G shows an example of a resulting structure.

Thereafter, the first main surface 153 of the carrier 150 is bonded to the first main surface 110 of the first semiconductor substrate 100 as indicated by the downward facing arrows in FIG. 3H. For example, this may be accomplished using an UV curable adhesive.

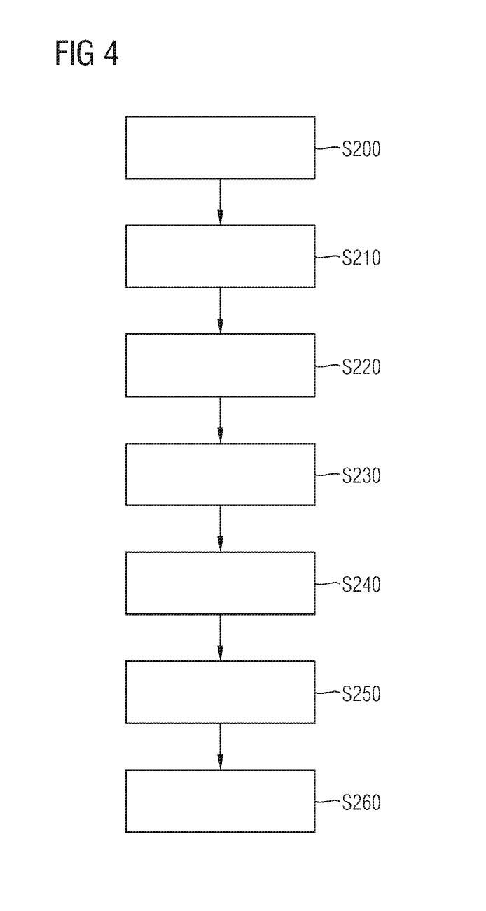

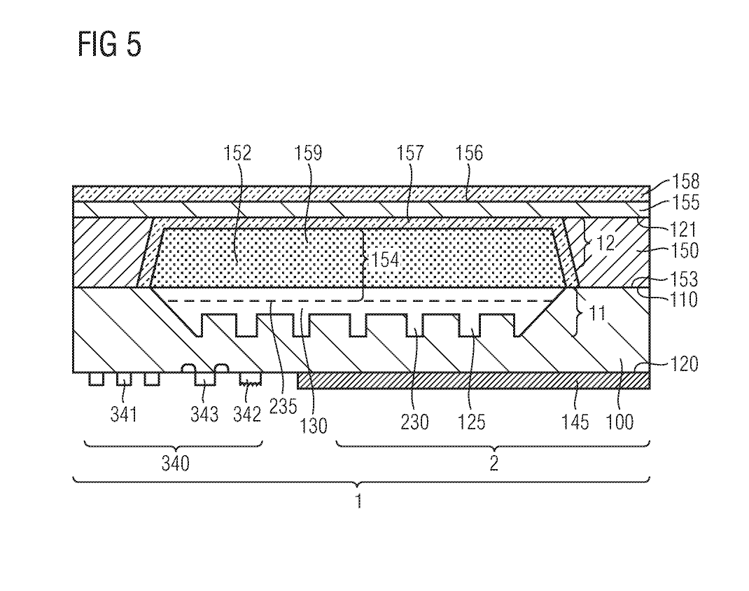

FIG. 4 summarizes a method according to an embodiment. As is shown, a method of manufacturing a battery comprises patterning a first main surface of a first semiconductor substrate to form a patterned portion in the first main surface (S200), forming an anode at the recessed portion (S210), forming a cathode at a carrier comprising an insulating material (S220), filling a suspension comprising a solvent and fibers into the patterned portion (S230), drying the solvent to form a separator (S240), filling an electrolyte into the patterned portion (S250), and stacking the first semiconductor substrate and the carrier (S260) so that the first main surface of the first semiconductor substrate is disposed on a side adjacent to a first main surface of the carrier.

FIG. 5 shows a cross-sectional view of an example of a battery 2 according to an embodiment. The battery 2 of FIG. 5 may be implemented as a lithium ion battery. The battery 2 shown in FIG. 5 comprises a first semiconductor substrate 100 having a first main surface 110. The battery 2 further comprises an anode 11 at the first semiconductor substrate 100, a carrier 150 comprising an insulating material, the carrier having a first main surface 153, and a cathode 12 at the carrier 150.

The first semiconductor substrate 100 and the carrier 150 are stacked so that the first main surface 110 of the first semiconductor substrate 100 is disposed on a side adjacent to the first main surface of the carrier 150, a cavity 154 being formed between the first semiconductor substrate 100 and the carrier 150. The battery 2 further comprises a separator comprising fibers and a binder in the cavity 154 and an electrolyte 230 in the cavity 154.

For example, the cavity 154 may comprise a recessed portion 130 in the first semiconductor substrate 100. Further, the cavity may comprise trenches 125 in the semiconductor substrate 100. According to an embodiment, the cavity 154 may further comprise an opening 152 formed in the carrier 150.

The anode 11 is disposed at the first semiconductor substrate 100. For example, the anode 11 may be integrally formed with the first semiconductor substrate 100 and may comprise a semiconductor material. The first semiconductor substrate 100 may be a silicon substrate. For example, the anode 11 may comprise silicon material which may be monocrystalline, polycrystalline or amorphous. The silicon material may be doped with any dopant as is conventionally used such as boron (B), arsenic (As), phosphorous (P), antimony (Sb), gallium (Ga), indium (In) or selenium (Se). The active silicon surface of the anode 11 may be planar or patterned. For example, three-dimensional structures such as trenches, pyramids and columns may be formed in the surface of the anode. According to an embodiment, the semiconductor material of the first semiconductor substrate 100 may form the anode. The semiconductor material may be further processed, e.g. by doping, patterning, etching, and by treating the surface of the semiconductor material. According to a further embodiment, a layer forming the anode may be formed on the first semiconductor substrate 100.

The cathode 12 is formed at the carrier. For example, the cathode may be formed adjacent to a top side or a bottom side of the carrier. The cathode may be formed on a support member that is attached to the carrier. The cathode may comprise one or more cathode materials. As a cathode material, generally known materials that are used in lithium ion batteries, such as LiCoO₂, LiNiO₂, LiNi₁₋ₓCoₓO₂. Li(NiO_{0.85}Co_{0.1}Al_{0.05})O₂, Li(Ni_{0.33}Co_{0.33}Mn_{0.33})O₂, LiMn₂O₄ spinel and LiFePO₄. As a further example, the cathode may comprise a matrix of NiCoAl oxide (NCA) including intercalated lithium. The materials forming the cathode may be implemented as a layer formed over a suitable substrate or the carrier.

The carrier 150 comprises an insulating material. For example, the carrier 150 may be made of the insulating material, e.g. an insulating polymer or glass. Alternatively, the carrier may comprise several layers including an insulating layer.

The electrolyte 230 may include electrolytes commonly used for lithium batteries such as e.g. LiPF₆, LiBF₄ or salts which do not include fluorine such as LiPCl₆, LiCIO₄, in water-free aprotic solvents such as propylene carbonate, dimethyl carbonate or 1,2-dimethoxymethane, ethylene carbonate, diethyl carbonate and others, polymers, for example polyvinylidene fluoride (PVDF) or other polymers, solid electrolytes such as Li₃PO₄N and others. For example, liquid electrolytes may be used, for example, electrolytes that do not withstand high temperatures that are higher than 80° C. As is to be clearly understood, also solid or liquid electrolytes that withstand temperatures higher than 80° C. may be used. As will become apparent from the following description, if fluorine-free salts and fluorine-free solvents are used as electrolytes, problems may be avoided when the housing of the battery includes components made of glass.

The separator 235 spatially and electrically separates the anode 11 and the cathode 12 from each other. The separator 235 may, for example, be formed as described above.

Due to the special composition of the separator and the specific method of manufacturing the separator, a plurality of batteries may be processed in parallel by an automated process of forming the separator. As a result, the manufacturing cost may be reduced. Moreover, due to the special feature that the separator is introduced as a suspension, followed by a process of drying the solvent, the separator is also formed in the single trenches 125. As a result, the separator may improve the mechanical stability of the micro-structured anode. For example, when the Si-based anode expands during the lithiation process, i.e. the charging of the Li micro battery, this volume expansion will not degrade the characteristics of the battery since the separator may improve the mechanical stability of the anode. Further, the separator may absorb the mechanical expansion of the micro-structured anode during charging and discharging cycling which results in increased mechanical stability of the micro battery system. Further, due to the special micro structure, the separator may provide the required mechanical flexibility to keep the Li micro battery mechanically stable during the charging and discharging cycling. Further, due to the presence of the binder a porous three-dimensional structure of fibers may be formed which provides an additional mechanical stability to the anode structures. In particular, by appropriately selecting the binder, the porosity may be adjusted. For example, the cavity volume may be 4.5 mm×4.5 mm×0.2 mm resulting in a cavity volume of 1 to 100 μl depending on the application. For example, the separator may have a thickness of 10 to 10 000 μm. When the separator is formed by pipetting, the thickness may have a range of 10 to 300 μm, e.g. 50 to 200 μm.

The battery 2 may be a rechargeable or secondary lithium ion battery. According to a further embodiment, the battery may be a primary battery which is not rechargeable. The battery 2 described herein has an improved capacity for energy storage, since silicon has a large capacity of insertion of lithium. In other words, the amount of lithium atoms that can be stored or inserted in silicon is much larger than in conventional cases. Since—as will be discussed in the following—the first substrate may comprise a semiconductor material, general semiconductor processing methods may be employed. In particular, methods for manufacturing miniaturized sizes can effectively applied for manufacturing a battery having a small size in comparison to conventional batteries. Further, components of an integrated circuit 1 may be easily integrated with the battery 2.

The integrated circuit 1 shown in FIG. 5 may further comprise different circuit elements 340 such as conductive lines 341, resistors 342, transistors 343, and further switches, for example.

The circuit elements 340 may be arranged in or on an arbitrary semiconductor material. For example, they may be arranged adjacent to the second main surface 120 of the first semiconductor substrate 100 or adjacent to the second main surface 156 of the second substrate 155.

Generally, the length and width of the battery may be in a range of 5 to 15 mm. For example, a size of the battery may be approximately 10 mm×10 mm. The length and the width of an active area in which the cavity 154 is formed may be in a range of 3.5 to 5.5 mm. For example, a size of the active area may be approximately 4.5 mm×4.5 mm. The shape of the battery and of the active area need not be quadratic.

According to the embodiment shown in FIG. 5, the second substrate 155 and/or the conductive layer 158 laterally extend to the same width as the first semiconductor substrate 100. For example, the second substrate 155 and/or the conductive layer 158 may be stacked over the carrier 150 and the first semiconductor substrate 100 so as to cover a bonding area which is disposed at an edge of the carrier 150 and the first semiconductor substrate 100.

The method and the battery described herein may be modified in a variety of manners. In particular, the method of assembling and defining the housing and of defining the cathode may vary. The further components may be manufactured by known methods.

Generally, within the context of the present specification, the electric circuit or the integrated circuit may comprise a processing device for processing data. The electric circuit or the integrated circuit may further comprise one or more display devices for displaying data. The electric circuit or the integrated circuit may further comprise a transmitter for transmitting data. The electric device or the integrated circuit may further comprise components which are configured to implement a specific electronic system. According to an embodiment, the electric device or the integrated circuit may further comprise an energy harvesting device that may deliver electrical energy to the battery 2, the energy having been generated from solar, thermal, kinetic or other kinds of energy. For example, the electric device or the integrated circuit may be a sensor such as a tire pressure sensor, wherein the electric circuit or the integrated circuit further comprises sensor circuitry and, optionally, a transmitter that transmits sensed data to an external receiver. According to another embodiment, the electric device or the integrated circuit may be an actuator, an RFID tag or a smartcard. For example, a smartcard may additionally comprise a fingerprint sensor, which may be operated using energy delivered by the battery 2.

While embodiments of the invention have been described above, it is obvious that further embodiments may be implemented. For example, further embodiments may comprise any subcombination of features recited in the claims or any subcombination of elements described in the examples given above. Accordingly, the spirit and scope of the appended claims should not be limited to the description of the embodiments contained herein.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of manufacturing a battery, comprising:
introducing a suspension comprising a solvent and fibers into a cavity for housing an electrolyte;
drying the solvent;
filling the electrolyte into the cavity; and
closing the cavity.

2. The method of claim 1, wherein the suspension is filled into the cavity by pipetting.

3. The method of claim 1, wherein the suspension further comprises a binder.

4. The method of claim 1, wherein the fibers comprise borosilicate glass fibers, polyethylene/polypropylene fibers, ZrO₂ fibers, Al₂O₃ fibers, SiO₂ fibers, polyimide fibers, paper fibers or cellulose fibers.

5. The method of claim 1, wherein the binder comprises PVDF, polyvinylidene fluoride, Na-carboxy methyl cellulose, or styrol butadiene rubber.

6. A method of manufacturing a battery, comprising:
patterning a first main surface of a first semiconductor substrate to form a patterned portion in the first main surface;
forming an anode at the patterned portion;
forming a cathode at a carrier comprising an insulating material;
filling a suspension comprising a solvent and fibers into the patterned portion; drying the solvent to form a separator,
filling an electrolyte into the patterned portion; and
stacking the first semiconductor substrate and the carrier so that the first main surface of the first semiconductor substrate is disposed on a side adjacent to a first main surface of the carrier.

7. The method of claim 6, wherein the suspension is filled into the patterned portion by pipetting.

8. The method of claim 6, wherein the suspension further comprises a binder.

9. The method of claim 6, wherein the fibers comprise borosilicate glass fibers, polyethylenelpolypropylene fibers, ZrO₂ fibers, Al₂O₃ fibers, SiO₂ fibers, polyimide fibers, paper fibers or cellulose fibers.

10. The method of claim 8, wherein the binder comprises PVDF, polyvinylidene fluoride, Na-carboxy methyl cellulose, or styrol butadiene rubber.

11. The method of claim 6, wherein the battery is a lithium ion battery and the anode comprises a silicon material.

12. A battery, comprising:
a first semiconductor substrate having a first main surface;
an anode at the first semiconductor substrate;
a carrier comprising an insulating material, the carrier having a first main surface;
a cathode at the carrier;
the first semiconductor substrate and the carrier being stacked so that the first main surface of the first semiconductor substrate is disposed on a side adjacent to the first main surface of the carrier, a cavity being formed between the first semiconductor substrate and the carrier;
a separator comprising fibers and a binder in the cavity; and
an electrolyte in the cavity.

13. The battery of claim 12, wherein the fibers comprise borosilicate glass fibers, polyethylene/polypropylene fibers, ZrO₂ fibers, Al₂O₃ fibers, SiO₂ fibers, polyimide fibers, paper fibers or cellulose fibers.

14. The battery of claim 12, wherein the binder comprises PVDF, polyvinylidene fluoride, Na-carboxy methyl cellulose, or styrol butadiene rubber.

15. The battery of claim 12, wherein the battery is a lithium ion battery and the anode comprises a silicon material.

16. An integrated circuit comprising the battery of claim 12 and a circuit element.

17. The integrated circuit of claim 16, wherein the circuit element is formed in the first semiconductor substrate.

18. The integrated circuit of claim 16, wherein the circuit element is selected from the group consisting of:
an energy receiving device, an energy emitting device, a signal processing circuit, an information processing circuit, an information storing circuit, a transistor, a capacitor, a resistor, a micro-electro-mechanical system, MEMS device, a sensor, an actuator, an energy harvester, a device for convening energy, a display device, a video device, an audio device, a music player and components of any of the devices.

19. An electronic device comprising the integrated circuit of claim 16.

20. The electronic device of claim 19, wherein the electronic device is selected from the group consisting of:
a sensor, an actuator, an RFID (radio frequency identification device) tag and a smartcard.
